(19) United States
(12) Patent Application Publication
(10) Pub. No.: US 2025/0140625 A1
(43) Pub. Date: May 1, 2025

(54) SEMICONDUCTOR MODULE AND METHOD OF MANUFACTURING A SEMICONDUCTOR MODULE

(71) Applicant: FUJI ELECTRIC CO., LTD., Kawasaki-shi (JP)

(72) Inventor: Yoshihiro YASUDA, Matsumoto-city (JP)

(73) Assignee: FUJI ELECTRIC CO., LTD., Kawasaki-shi (JP)

(21) Appl. No.: 18/816,197

(22) Filed: Aug. 27, 2024

(30) Foreign Application Priority Data
Oct. 30, 2023 (JP) 2023-185178

(51) Int. Cl. H01L 23/31; H01L 21/56; H01L 23/06; H01L 23/495; H01L 25/00; H01L 25/065

(52) U.S. Cl. CPC H01L 23/3135; H01L 21/56; H01L 23/06; H01L 25/0655; H01L 25/50; H01L 23/495

(57) ABSTRACT

A semiconductor module includes a stacked substrate, a semiconductor device mounted to the stacked substrate, a case housing encapsulated members that include the semiconductor device and the stacked substrate, an encapsulant filling in the case to encapsulate the encapsulated members, and a mica sheet provided on an upper surface of the encapsulant. The encapsulant includes a gel at a position facing the mica sheet and the mica sheet is provided on the gel.

### CROSS REFERENCE TO RELATED APPLICATIONS

This application is based upon and claims the benefit of priority of the prior Japanese Patent Application No. 2023-185178, filed on Oct. 30, 2023, the entire contents of which are incorporated herein by reference.

### BACKGROUND OF THE INVENTION

### 1. Field of the Invention

Embodiments of the invention relate to a semiconductor module and a method of manufacturing a semiconductor module.

### 2. Description of the Related Art

A conventionally known power module includes one or more power semiconductor chips, a case housing the power semiconductor chip(s), and a silicone gel filling the case and encapsulating the power semiconductor chip(s) (for example, refer to Japanese Laid-Open Patent Publication No. 2014-216558).

### SUMMARY OF THE INVENTION

According to an embodiment of the present disclosure, a semiconductor module includes: a stacked substrate; a semiconductor device mounted on the stacked substrate; a case housing encapsulated members including the semiconductor device and the stacked substrate; an encapsulant filling the case to encapsulate the encapsulated members; and a mica sheet provided on an upper surface of the encapsulant. The encapsulant includes a gel at a position facing the mica sheet and the mica sheet is provided on the gel.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a configuration of a semiconductor module according to an embodiment.

FIG. 2 is a top view depicting the configuration of the semiconductor module according to the embodiment.

FIG. 3 is a cross-sectional view depicting conveyance of the semiconductor module according to the embodiment.

FIG. 4 is a flowchart showing a method of manufacturing the semiconductor module according to the embodiment.

FIG. 5 is a cross-sectional view depicting conveyance of a conventional semiconductor module encapsulated by an epoxy resin.

FIG. 6 is a cross-sectional view depicting conveyance of a conventional semiconductor module encapsulated by a gel.

### DETAILED DESCRIPTION OF THE INVENTION

First, problems associated with the conventional techniques are discussed. In a conventional semiconductor module, when a gel is employed as an encapsulant, a problem arises in that the gel is adherent even after curing and thus, conveyance is adversely affected.

In light of the problems described a semiconductor module according to the present disclosure has following features. The semiconductor module includes a stacked substrate; a semiconductor device mounted to the stacked substrate; a case housing encapsulated members including the semiconductor device and the stacked substrate; an encapsulant filling the case and encapsulating the encapsulated members; and a mica sheet provided on an upper surface of the encapsulant. The encapsulant includes a gel facing the mica sheet and the mica sheet is provided on the gel.

According to the disclosure above, the mica sheet itself is not adherent and has excellent insulating and flame retardant properties, enabling conveyance by attaching a suction nozzle to the upper surface by suction, thereby enabling improved conveyance. Thus, replacement of equipment for conveying the semiconductor module in which a gel is used as an encapsulant is unnecessary and depreciation expenses, etc. may be reduced.

Further, in the disclosed semiconductor module, in the disclosure above, the encapsulant encapsulates the encapsulated members by the gel.

Further, in the disclosed semiconductor module, in the disclosure above, the encapsulant includes a resin provided in a portion of the case, the portion housing the semiconductor device and the gel is provided on the resin.

According to the disclosure above, movement of a layer bonding the semiconductor device and the stacked substrate due to stress may be prevented.

Further, in the disclosed semiconductor module, in the disclosure above, the mica sheet covers at least 10% of an area of an upper surface of the gel.

Further, in the disclosed semiconductor module, in the disclosure above, the mica sheet has a thickness in a range of 0.2 mm to 0.5 mm.

According to the disclosure above, deformation of the gel may be suppressed and it may be ensured that the mica sheet follows the contour of the surface of the gel.

In light of the problems described a method of manufacturing a semiconductor module according to the present disclosure has following features. The method of manufacturing the semiconductor module includes bonding a semiconductor device to a stacked substrate; mounting a case to the stacked substrate; applying a gel in the case; curing the gel; and mounting a mica sheet to an upper surface of the gel.

Further, the disclosed method of manufacturing the semiconductor module, in the disclosure above, further includes after mounting the stacked substrate but before applying the gel, injecting a resin in the case and curing the resin.

Here, problems associated with the conventional semiconductor module are discussed. The conventional semiconductor module includes a semiconductor chip, a stacked substrate, a case, a heat dissipating base, and a metal wire. The semiconductor chip is a power semiconductor chip such as a metal-oxide-semiconductor field effect transistor (MOSFET), an insulated gate bipolar transistor (IGBT), or a diode, and is bonded on the stacked substrate by a bonding layer such as a solder. The stacked substrate refers to an insulated substrate such as a ceramic substrate having, at a front surface thereof, a first conductive plate containing, for example, copper and at a back surface, a second conductive plate containing, for example, copper. The stacked substrate is bonded to a heat dissipating base by a bonding layer such as a solder. Further, in an instance of a MOSFET, a source electrode pad is formed as a power terminal electrode pad (current supply terminal) at a surface of the semiconductor chip. Further, a conductive connecting member such as a lead frame or a metal wire is disposed as a lead terminal from the power terminal electrode pad. The case is mounted to the semiconductor module and a cover through which metal terminals penetrate and protrude externally is attached. The case is filled with the encapsulant, which insulates and protects the stacked substrate and the semiconductor chip on the substrate from the external environment.

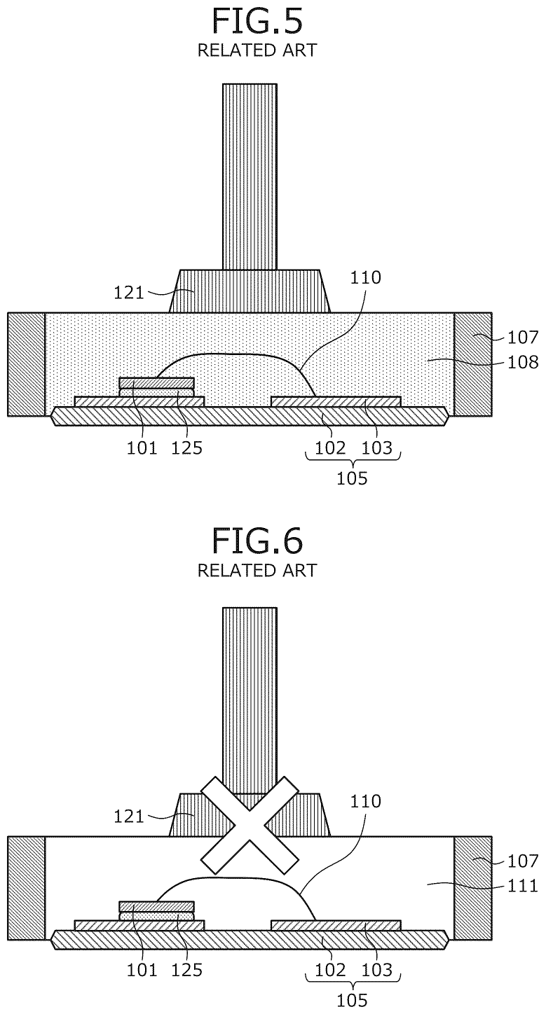

FIG. 5 is a cross-sectional view depicting conveyance of a conventional semiconductor module encapsulated by an epoxy resin. FIG. 5, depicts a semiconductor module in which an epoxy resin 108 is used as an encapsulant; the semiconductor module includes a semiconductor chip 101, a stacked substrate 105 having an insulated substrate 102 and a first conductive plate 103, a case 107, the epoxy resin 108, a metal wire 110, and a bonding layer 125.

In a manufacturing process, when the semiconductor module is conveyed, a suction nozzle 121 is attached to the surface of the epoxy resin 108 by suction to convey the semiconductor module. The surface of the epoxy resin 108 is solidified after curing and thus, no problems with suctioning occurs.

However, when the epoxy resin 108 is used, a problem arises in that for small capacity module products, when a short-circuit is created by cracks in a circuit or the chip, the circuit is not destroyed by a pressing force due to epoxy resin curing shrinkage and overcurrent continues to be applied due to large current driving, until eventually the circuit ignites.

Thus, to block the conduction path during the initial ignition, a method of employing a gel 111 as an encapsulant instead of the epoxy resin 108 has been proposed. FIG. 6 is a cross-sectional view depicting conveyance of a conventional semiconductor module encapsulated by a gel. When the gel 111 is used as an encapsulant, the gel 111 itself is adherent even when cured and thus, a problem arises in that the semiconductor module cannot be removed from the suction nozzle 121, making such conveyance difficult and adversely affecting conveyance in a manufacturing facility.

Embodiments of a semiconductor module and a method of manufacturing a semiconductor module according to the present disclosure are described in detail with reference to the accompanying drawings. However, the present disclosure is not limited to the embodiments described herein.

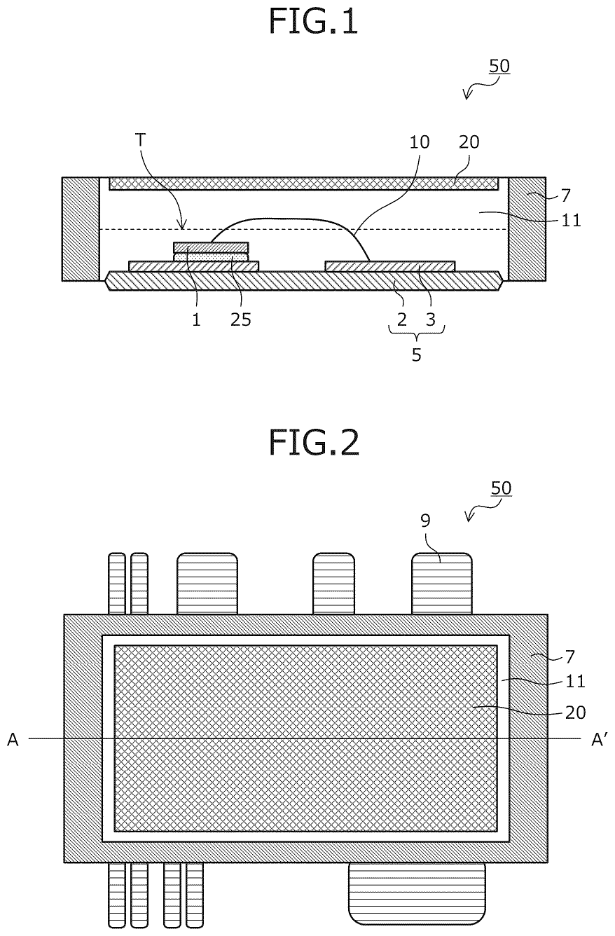

A semiconductor module according to an embodiment solving the problems above is described. FIG. 1 is a cross-sectional view depicting a configuration of the semiconductor module according to the embodiment. FIG. 2 is a top view depicting the configuration of the semiconductor module according to the embodiment. FIG. 1 depicts a cross-section along cutting line A-A′ in FIG. 2. In a semiconductor module 50, a first conductive plate 3 that contains copper is disposed at a front surface of an insulated substrate 2 and a second conductive plate (not depicted) that contains copper or the like is disposed at a back surface of the insulated substrate 2, whereby a stacked substrate 5 is formed. Multiple semiconductor chips (semiconductor devices) 1 are mounted to a front surface of the first conductive plate 3 of the stacked substrate 5, via a bonding layer 25 containing a solder or a sintered material. The first conductive plate 3 is formed by a predetermined circuit pattern at the front surface (first main surface) of the insulated substrate 2. The second conductive plate of a back surface of the stacked substrate 5 is bonded to a front surface of a heat dissipating base (not depicted) by a bonding layer (not depicted) containing a solder, a sintered material, or the like. The second conductive plate may be a metal foil formed in an entire area of the back surface of the insulated substrate 2.

Metal terminals 9 for external output of signals are bonded in a case 7. Further, at front surfaces (for example, source electrode pad) of the semiconductor chips 1, a conductive connecting member such as a pin-type terminal, a lead frame, etc. is provided, via a metal wire 10 (bonding wire) such as an aluminum wire or a bonding layer (not depicted). Further, the semiconductor chips 1 and the metal terminals 9 are electrically connected by the metal wire 10 such as an aluminum wire or the like. A lead frame may be used. Further, the case 7 is filled with a gel 11 as an encapsulant.

Further, as the encapsulant, a hybrid of the gel 11 and an encapsulation resin may be used. In this instance, from line T in FIG. 1 to the semiconductor chips 1 is filled with the encapsulation resin such as an epoxy resin and above the encapsulation resin is filled with the gel 11. Line T corresponds to about a half of a height of the case 7. Preferably, the metal wire 10 may be encapsulated by the encapsulation resin. A reason for this is that in a temperature range of-50 degrees C. to 150 degrees C., the bonding layer 25 may move due to stress when only the gel 11 is used. In the embodiment, to improve conveyance, a mica sheet 20 is attached to an upper surface of the gel 11. The configuration of the semiconductor module 50 depicted is one example and the present disclosure is not limited hereto.

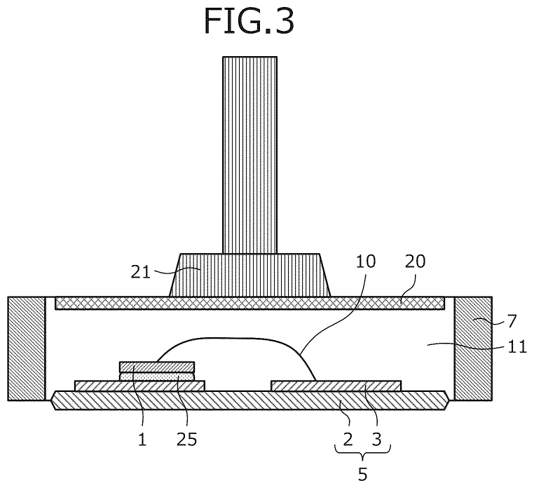

FIG. 3 is a cross-sectional view depicting conveyance of the semiconductor module according to the embodiment. The semiconductor module 50 of the present disclosure is used in small capacity module products. A small capacity module product is, for example, a product with a weight of not more than 300 g, more specifically, a product of a weight in a range of 50 g to 150 g. The small capacity module product is conveyed during a manufacturing process by attaching a suction nozzle 21 to an upper surface of the semiconductor module by suction. As depicted in FIG. 3, as for an upper surface of the gel 11, which is adherent, the mica sheet 20 is not adherent and thus, conveyance by attaching the suction nozzle 21 to the upper surface is possible and conveyance may be improved. Thus, replacement of equipment for conveying the semiconductor module 50 in which the gel 11 is used as the encapsulant becomes unnecessary and depreciation expenses and the like may be reduced.

The semiconductor chips 1 are power chips such as MOSFETs, IGBTs, Schottky barrier diodes (SBDs), etc., and devices that use Si, SiC, GaN as a semiconductor substrate may be used. The number of the semiconductor chips 1 that are mounted may be one or more.

The stacked substrate 5 is configured by the insulated substrate 2, the first conductive plate 3 formed in a predetermined shape at a first main surface of the insulated substrate 2, and the second conductive plate formed at a second main surface of the insulated substrate 2. A material having excellent electrical insulation and thermal conductivity may be used as the insulated substrate 2. A material of the insulated substrate 2 may be, for example, Al₂O₃, AlN, SiN, etc. In particular, in high voltage applications, a material achieving both electrical insulation and thermal conduction is preferable and AlN or SiN may be used, however, the material is not limited hereto. As for the first conductive plate 3 and the second conductive plate, copper (Cu) or a Cu alloy, which have excellent processibility may be used. The Cu alloy contains at least 80% Cu. Of the conductive plates containing Cu or a Cu alloy, the conductive plate not in contact with the semiconductor chips 1 may be referred to as a back copper foil or a back conductive plate. As a method of disposing the conductive plate on the insulated substrate 2, a direct copper bonding method or an active metal brazing method may be used. Further, nickel (Ni) plating may be implemented at a surface of the conductive substrate and a Ni or Ni alloy layer may be formed.

The bonding layer 25 may be formed using a lead-free solder. For example, without limitation hereto, a Sn—Sb type, a Sn—Cu type, a Sn—Ag type, a Sn—Sb—Ag type, etc. may be used. Further, the bonding layer 25 may be formed using a connecting material containing microscopic metal particles such as a sintered material of silver nanoparticles.

A lower end of the case 7 containing a resin or the like is adhered to a peripheral edge of a heat dissipating base. The case 7 has a substantially rectangular tube shape and surrounds a periphery of the front surface of the heat dissipating base. A box-like recess is formed, the recess having the front surface of the heat dissipating base as a bottom, and an inner wall of the case 7 orthogonal to the front surface of the heat dissipating base as sidewalls. The stacked substrate 5 and the semiconductor chips 1 connected by wiring members of the lead frame 10, etc., the wiring members, and components are housed in the recess. Further, a connector containing a Cu alloy may be used to wire the semiconductor chips 1 and the stacked substrate 5. A material of the case 7 may be, for example, a thermosetting resin such as a phenol formaldehyde resin, or a thermoplastic resin such as polybutylene terephthalate (PBT), polyphenylene sulfide (PPS), etc.

The gel 11 is highly viscous, loses fluidity, and solidifies. The gel 11, for example, is a silicone gel.

The mica sheet 20 has excellent insulation and flame retardancy and thus, is optimal for use as a cover of the semiconductor module 50. The mica sheet 20 has an elastic modulus of about 74 GPa±10% which, compared to an elastic modulus of silicone rubber in a range of 0.001 Gpa to 0.1 GPa, is a suitable elastic modulus and thus, the mica sheet 20 is less prone to excessive deformation and enables excellent transportability. Furthermore, the elastic modulus is not excessively large and thus, during application, the mica sheet 20 may follow the shape of the surface of the gel 11 and adherence is good.

Preferably, the shape of the mica sheet 20 may be a same as a shape of the upper surface of the semiconductor module 50 and preferably, an area of the mica sheet 20 may be at least equal to an area of the portion attached to the suction nozzle 21. The portion attached to the suction nozzle 21 has an elliptic or circular shape with a major axis length or diameter in a range of 30 mm to 50 mm and thus, preferably, a shape of the mica sheet 20 may be a rectangular shape with a lateral width in a range of 30 mm to 50 mm. Further, for example, preferably, the mica sheet 20 may be of a size that occupies 10% or more of the area of the upper surface of the gel 11. Furthermore, the mica sheet 20 may be applied in plural depending on the shape of the suction nozzle 21 for conveyance. Further, preferably, a thickness of the mica sheet 20 may be in a range of 0.2 mm to 0.5 mm to suppress deformation of the gel 11 and ensure that the mica sheet 20 follows the contour of the surface of the gel 11. In the embodiment, while the mica sheet 20 is used, another material may be used provided the material is flame retardant, provides insulation, is hard, and can follow the contour of the surface of the gel 11.

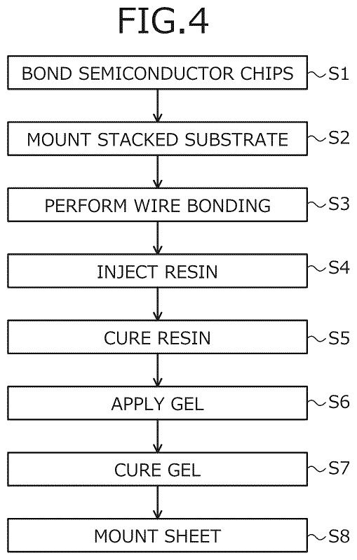

Next, a method of manufacturing the semiconductor module according to the embodiment is described. FIG. 4 is a flowchart showing the method of manufacturing the semiconductor module according to the embodiment. First, the semiconductor chips 1 are bonded to the heat dissipating base and the stacked substrate 5 by the bonding layer 25 (step S1: first process).

Thereafter, the case 7 is attached to the heat dissipating base and subsequently, the stacked substrate 5 is mounted to the case 7 (step S2: second process). Next, bonding of the lead frame and wire bonding via the metal wire 10 are performed (step S3).

Next, the encapsulation resin such as an epoxy resin is injected in the case 7 (step S4: sixth process). Next, the encapsulation resin is precured in a range of 100 degrees C. to 120 degrees C. for 10 minutes to 120 minutes and is cured in a range of about 175 degrees C. to 185 degrees C. for 1 hour to 2 hours (step S5: seventh process). Steps S4 and S5 are performed in an instance of a hybrid structure of the gel 11 and the encapsulation resin and are unnecessary in an instance when only the gel 11 is used and the encapsulation resin is omitted.

Next, the gel 11 is applied in the case 7 (step S6: third process). Next, the gel 11 is cured (step S7: fourth process). Next, the mica sheet 20 is mounted to the upper surface of the gel 11 (step S8: fifth process). During mounting, the mica sheet 20 may be placed on the upper surface of the gel 11 and pressed down. In the application of the mica sheet 20, the gel 11 itself is adherent and this property may be used or another adhesive may be used. When the adherent property of the gel 11 is used, the mica sheet 20 may be attached by merely being placed on the upper surface of the gel 11, an adhering process is unnecessary, thereby enabling reductions in facility costs and labor. As described, a semiconductor module 20 depicted in FIGS. 1 and 2 may be manufactured.

As described, according to the semiconductor module and the method of manufacturing the semiconductor module of the embodiment, the mica sheet itself is not adherent and has excellent insulating and flame retardant properties, enabling conveyance by attaching a suction nozzle to the upper surface by suction, thereby enabling improved conveyance. Thus, replacement of equipment for conveying the semiconductor module in which a gel is used as an encapsulant is unnecessary and depreciation expenses, etc. may be reduced.

In the foregoing, the present invention may be variously modified within a range not departing from the spirit of the invention and in the embodiments described, for example, dimensions, doping concentrations, etc. of regions may variously set according to necessary specifications. Further, in the embodiments described, other than silicon, a wide band gap semiconductor such as silicon carbide (SiC), gallium nitride (GaN), etc. may be employed as a semiconductor.

According to the disclosure above, the mica sheet itself is not adherent and has excellent flame retardant and insulating properties, enabling conveyance by attaching a suction nozzle to the upper surface by suction, thereby enabling improved conveyance. Thus, replacement of equipment for conveying the semiconductor module in which a gel is used as an encapsulant is unnecessary and depreciation expenses, etc. may be reduced.

The semiconductor module and the method of manufacturing the semiconductor module according to the present disclosure achieve an effect in that conveyance may be improved in an instance of a gel being employed as the encapsulant.

As described, the semiconductor module and the method of manufacturing the semiconductor module according to the present invention are useful for power semiconductor modules used in power converting equipment of inverters and the like, power source devices of various types of industrial machines and the like, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate;
a semiconductor device mounted on the stacked substrate;
a case housing encapsulated members including the semiconductor device and the stacked substrate;
an encapsulant filling the case to encapsulate the encapsulated members; and
a mica sheet provided on an upper surface of the encapsulant, wherein
the encapsulant includes a gel at a position facing the mica sheet and the mica sheet is provided on the gel.

2. The semiconductor module according to claim 1, wherein the encapsulant encapsulates the encapsulated members in the gel.

3. The semiconductor module according to claim 1, wherein the encapsulant includes a resin that encapsulates the semiconductor device and the gel that is provided on the resin.

4. The semiconductor module according to claim 1, wherein the mica sheet covers at least 10% of an area of an upper surface of the gel.

5. The semiconductor module according to claim 1, wherein the mica sheet has a thickness in a range of 0.2 mm to 0.5 mm.

6. A method of manufacturing a semiconductor module, the method comprising:
bonding a semiconductor device to a stacked substrate;
mounting the stacked substrate to a case;
applying a gel in the case;
curing the gel; and
mounting a mica sheet to an upper surface of the gel.

7. The method according to claim 6, further comprising after mounting the stacked substrate but before applying the gel, injecting a resin in the case to encapsulate the semiconductor device and curing the injected resin.
